(19) United States
(12) Patent Application Publication
(10) Pub. No.: US 2024/0186248 A1
(43) Pub. Date: Jun. 6, 2024

(54) BACKSIDE POWER DELIVERY NETWORK

(71) Applicant: ADEIA SEMICONDUCTOR BONDING TECHNOLOGIES INC., San Jose, CA (US)

(72) Inventors: Belgacem HABA, Saratoga, CA (US); Cyprian Emeka UZOH, San Jose, CA (US); Rajesh KATKAR, Milpitas, CA (US)

(21) Appl. No.: 18/523,131

(22) Filed: Nov. 29, 2023

Related U.S. Application Data
(60) Provisional application No. 63/385,754, filed on Dec. 1, 2022.

(51) Int. Cl. H01L 23/528; H01L 23/00; H01L 23/367; H01L 23/498; H01L 25/065

(52) U.S. Cl. CPC H01L 23/5286; H01L 23/3672; H01L 23/49816; H01L 23/49822; H01L 24/05; H01L 24/13; H01L 25/0657; H01L 2224/05009; H01L 2224/05025; H01L 2224/13007; H01L 2224/13026; H01L 2225/06513; H01L 2225/06527; H01L 2924/01029; H01L 2924/1427; H01L 2924/1431; H01L 2924/15311

(57) ABSTRACT

An assembly may include a reconstituted element having a front surface and a back surface, the reconstituted element comprising: a semiconductor die having a front side and a back side, the semiconductor die including circuitry closer to the front side than to the back side and a via extending from the back side of the semiconductor die to connect to the circuitry, an insulating material disposed along a side surface of the semiconductor die, a power rail extending from the front surface to the back surface of the reconstituted element and configured to deliver power to the semiconductor die; and an interconnect structure configured to electrically connect the power rail to the via and to deliver power to the semiconductor die from the back side of the semiconductor die.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the benefit of U.S. Provisional Application No. 63/385,754, filed Dec. 1, 2022, the content of which is incorporated by reference in its entirety for and for all purposes.

### BACKGROUND

### Field

This disclosure relates to semiconductor device structures. Some embodiments relate to backside power delivery.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As features in semiconductor devices continue to shrink, power delivery issues are of increasing concern, as electrical isolation issues, limitations on feature sizes, losses due to traversing large numbers of metal layers, and so forth make it difficult to efficiently provide power to semiconductor devices. Backside power delivery can provide relief by separating power delivery from signal routing. However, backside power delivery presents several challenges and can significantly complicate manufacturing processes.

### SUMMARY

The systems, methods, and devices described herein each have several aspects, no single one of which is solely responsible for its desirable attributes. Without limiting the scope of this disclosure, several non-limiting features will now be described briefly.

In some aspects, the techniques described herein relate to an assembly including: a reconstituted element having a front surface and a back surface, the reconstituted element including: a semiconductor die having a front side and a back side, the semiconductor die including circuitry closer to the front side than to the back side and a via extending from the back side of the semiconductor die to connect to the circuitry; an insulating material disposed along a side surface of the semiconductor die; a power rail extending from the front surface to the back surface of the reconstituted element and configured to deliver power to the semiconductor die; and an interconnect structure configured to electrically connect the power rail to the via and to deliver power to the semiconductor die from the back side of the semiconductor die.

In some aspects, the techniques described herein relate to an assembly, wherein the insulating material includes an inorganic dielectric.

In some aspects, the techniques described herein relate to an assembly, wherein the insulating material includes silicon oxide.

In some aspects, the techniques described herein relate to an assembly, wherein the insulating material includes an organic dielectric.

In some aspects, the techniques described herein relate to an assembly, wherein the interconnect structure includes a redistribution layer disposed on the back surface of the reconstituted element.

In some aspects, the techniques described herein relate to an assembly, wherein the interconnect structure includes an interconnect element that is hybrid bonded to the back side of the semiconductor die.

In some aspects, the techniques described herein relate to an assembly, wherein the interconnect structure includes one or more metallization layers.

In some aspects, the techniques described herein relate to an assembly, further including a power delivery die, wherein the power delivery die is hybrid bonded to the back surface of the reconstituted element.

In some aspects, the techniques described herein relate to an assembly, wherein the power delivery die includes a redistribution layer.

In some aspects, the techniques described herein relate to an assembly, wherein the reconstituted element further includes an integrated voltage regulator.

In some aspects, the techniques described herein relate to an assembly, further including a dummy die, wherein the dummy die is directly bonded to the back surface of the reconstituted element.

In some aspects, the techniques described herein relate to an assembly, further including a second reconstituted element, the second reconstituted element including: an integrated voltage regulator; and integrated power delivery circuitry, wherein the second reconstituted element is hybrid bonded to the reconstituted element.

In some aspects, the techniques described herein relate to an assembly, further including a dummy die, the dummy die directly bonded to the second reconstituted element.

In some aspects, the techniques described herein relate to an assembly, further including a stack, wherein the stack comprises a dummy die directly bonded to the second reconstituted element.

In some aspects, the techniques described herein relate to an assembly, further including: an integrated voltage regulator element, the integrated voltage regulator element hybrid bonded to the reconstituted element.

In some aspects, the techniques described herein relate to an assembly, wherein the reconstituted element further includes a dummy semiconductor element, wherein the power rail is disposed in the dummy semiconductor element.

In some aspects, the techniques described herein relate to an assembly, wherein the reconstituted element further includes an integrated voltage regulator, wherein the assembly further includes a power delivery die, the power delivery die including a one or more memory banks.

In some aspects, the techniques described herein relate to an assembly, further including an optical input/output system, the optical input/output system bonded to the front surface of the reconstituted element.

In some aspects, the techniques described herein relate to an assembly, further including: a second reconstituted element, the second reconstituted element hybrid bonded to the reconstituted element, wherein the second reconstituted element includes: integrated power delivery circuitry; one or more memory banks; and one or more integrated voltage regulators.

In some aspects, the techniques described herein relate to an assembly, wherein the circuitry comprises one or more transistors.

In some aspects, the techniques described herein relate to an assembly, wherein the semiconductor die has a thickness less than 5 μm.

In some aspects, the techniques described herein relate to an assembly, wherein the semiconductor die has a thickness less than 1 μm.

In some aspects, the techniques described herein relate to an assembly, wherein the semiconductor die is a logic die or a processor die.

In some aspects, the techniques described herein relate to an assembly including: an insulating material; a power rail extending through the insulating material; an integrated device die at least partially embedded in the insulating material, the integrated device die having a front side and a back side, the integrated device die including circuitry closer to the front side than to the back side and a power delivery structure extending from the back side of the integrated device die to connect to the circuitry; and an interconnect structure over the insulating material, the power rail, and the back side of the integrated device die, the interconnect structure configured to deliver power between the power rail and the power delivery structure at the back side of the integrated device die.

In some aspects, the techniques described herein relate to an assembly, wherein the insulating material comprises an inorganic dielectric material.

In some aspects, the techniques described herein relate to an assembly, further including a power delivery die hybrid bonded to the interconnect structure.

In some aspects, the techniques described herein relate to an assembly, further including a dummy die, wherein the dummy die is directly bonded to the interconnect structure.

In some aspects, the techniques described herein relate to a method for forming a bonded structure having backside power delivery, the method including: forming a bonding surface on a back surface of a reconstituted element, the reconstituted element having a front surface and back surface, wherein the reconstituted element includes: a semiconductor die having a front side and a back side, the die including circuitry closer to the front side than to the back side and a via extending from the back side of the die to connect to the circuitry; an insulating material disposed along a side surface of the semiconductor die; a power rail extending from the front surface to the back surface of the reconstituted element and configured to deliver power to the semiconductor die; and an interconnect structure configured to electrically connect the power rail to the via and to deliver power to the semiconductor die from the back side of the semiconductor die; and directly bonding a second element to the bonding surface of the reconstituted element.

In some aspects, the techniques described herein relate to a method, wherein the second element includes an integrated voltage regulator.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a side view of an example device according to some embodiments.

FIG. 1B illustrates a backside view of an example device according to some embodiments.

FIG. 1C illustrates a side view of an example device comprising dummy silicon according to some embodiments.

FIG. 2 illustrates an example device comprising a power delivery die according to some embodiments.

FIG. 3 illustrates an example device comprising a dummy die according to some embodiments.

FIG. 4 illustrates an example device comprising reconstituted power delivery layer and a dummy die according to some embodiments.

FIG. 5 illustrates an example device comprising a power delivery layer and dummy die according to some embodiments.

FIG. 6 illustrates an example device comprising a memory bank layer according to some embodiments.

FIG. 7 illustrates an example device comprising a reconstituted power delivery layer that includes memory banks and a dummy die according to some embodiments.

FIG. 8 is a flowchart that illustrates an example process for making an assembly including backside power according to some embodiments.

FIGS. 9A and 9B schematically illustrate a direct bonding process according to some embodiments.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and includes other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

In conventional semiconductor devices, signal transmission and power delivery both take place through the frontside of the device. As device features continue to shrink, it is increasingly difficult to provide both power and signal through the frontside of a device without adversely affecting the device performance. For example, as semiconductor devices increase in density and complexity, the number of metal layers that include signal and power lines also tends to increase, effectively increasing the length of the wires and reducing the size (e.g., cross-sectional area) of the interconnects that carry power to the transistors. This can result in significant power losses due to the high resistance of the thin copper commonly used for frontside power delivery. For example, typical devices can be designed to accommodate power delivery losses (e.g., voltage drops) of about 10%. However, larger voltage drops can be seen at smaller manufacturing nodes and when there are many (e.g., about 10, about 15, about 20, or more) metal layers. In some processes, metal interconnects can comprise alternative materials such as cobalt or tungsten, for example in lower back end of line (BEOL) levels, which can reduce losses, but the benefits of using other conductive materials is limited and a radically different approach may be needed. Moreover, the power lines occupy significant real estate on the front side of the chip and the device, effectively increasing device cell sizes and chip sizes.

Backside power delivery can relieve some problems associated with scaling of semiconductor devices to smaller process nodes, including reducing on-chip IR drop, scaling chip area, reducing back-end-of-line (BEOL) complexity, etc. For example, backside power delivery can alleviate congestion on the frontside by eliminating or reducing the need to route power via the front side. Backside power delivery can enable shorter, wider, and thicker lines (which can have lower resistance than longer, thinner lines) to be used for power delivery, which can reduce power delivery losses. Backside power delivery can also enable significant space savings, facilitating increased density. Additionally, backside power delivery can improve signal integrity as power delivery is relatively far-removed from signal transmission, thereby reducing the potential for power delivery to interfere with signal transmission.

While backside power delivery offers many potential benefits, there can be significant challenges to manufacturing devices with backside power delivery like extreme substrate thinning (e.g., under 1 μm), backside to frontside alignment, heat dissipation due to sandwiching of device silicon between dielectric layers for signal routing on the front side and power routing on the backside, etc. For example, backside power delivery implementations can use direct bonding, which may distort or warp the structures and may complicate subsequent processing. Material choices for vias can be limited as backside power delivery components can be formed relatively early in the manufacturing process, potentially before front-end-of-line (FEOL) processing is complete. Thus, it may be impractical or impossible to use some materials such as copper, and it can be important to select materials that can withstand the high processing temperatures used in preparing high quality semiconductor devices on advanced manufacturing processes.

Some embodiments herein can provide frontside package-level access to power and ground rails, as well as signal lines, while providing backside power delivery to a device die. In some embodiments, relatively large power and/or ground rails can be disposed outside of a die footprint, enabling the delivery of power from the front of a package to the backside of the die without large voltage drops. In some embodiments, backside power lines can be accessible for efficient thermal extraction of heat generated during operation. In some embodiments, the power and/or ground rails can be provided outside the die area using a reconstitution approach. In some embodiments, integrated voltage regulators, passives, and so forth may have different dimensions than a device die. which can make the use reconstituted wafers or elements particularly appealing. As used herein, the term “power” can, unless context clearly requires otherwise, be interpreted as including positive potential, negative potential, and/or zero potential (e.g., ground).

As described herein and in the accompanying drawings, in some backside power delivery embodiments, direct bonding and/or direct hybrid bonding, as described in more detail herein, can be used to form semiconductor device assemblies with backside power delivery and/or other features. While the examples herein depict direct bonds or direct hybrid bonds in particular locations within a device stack, it will be appreciated that the particular location of a direct bond or direct hybrid bond may vary depending upon the specific implementation.

In addition to reduced losses due to resistance within the metal layers and interfaces and reduced signal integrity concerns, backside power delivery can enable more efficient cooling because the power lines, which can be a large source of Joule heating, can be accessible to attach cooling solutions such as heat spreaders, liquid cooling, and so forth. For example a cooling solution can be attached to a side of the die that is relatively close to the power lines as compared with some other integrated circuit device designs. For example, typically, a packaged device die has the front side facing downward (e.g., towards a printed circuit board or socket to which the device die is mounted). If power delivery circuitry is provided on the back of the die, the power delivery circuitry can be closer to heat spreaders, heatsinks, liquid cooling, fans, or other cooling means that can be attached to the exposed side of the device. In various embodiments disclosed herein, the active circuitry (e.g., transistor(s)) of an element (e.g., a die) can be located nearer to the frontside of the element than to the backside of the element.

As discussed briefly above, in some embodiments, power delivery can be initiated at a front side of a die or package and routed to the backside for backside power delivery. In some embodiments, a die can include signal pads but may not include power rails. Instead, power rails can be formed outside of the die in a surrounding dielectric (e.g., an inorganic dielectric such as silicon oxide) as part of a reconstituted wafer or reconstituted element. In some embodiments, a logic die can include signal wiring. In some embodiments, a logic die can include buried power rails, power vias, or backside contacts (BSC) to source and/or drains (e.g., backside direct source contacting). In some embodiments, a logic die can include blind backside-through silicon vias (TSVs). In some embodiments, a logic die can form part of a reconstituted element or reconstituted wafer. For example, the logic die can be reconstituted onto a dummy or sacrificial carrier and power rails and/or ground rails can be formed in the reconstituted wafer at the periphery of the logic die. In some embodiments, a direct bonding interface can be formed on a back surface of the reconstituted element. In some embodiments, backside power delivery can be facilitated by direct bonding power delivery circuitry to and/or depositing power delivery circuitry on the backside of the reconstituted element. In some embodiments, the direct bonded power delivery circuitry can comprise silicon (e.g., a silicon wafer). In some embodiments, the direct bonded power delivery circuitry can comprise a reconstituted element and can include passives (e.g., resistors, inductors, capacitors, etc.), integrated voltage regulators, and so forth. A backside power delivery network can be configured to provide one or more voltages to the logic die.

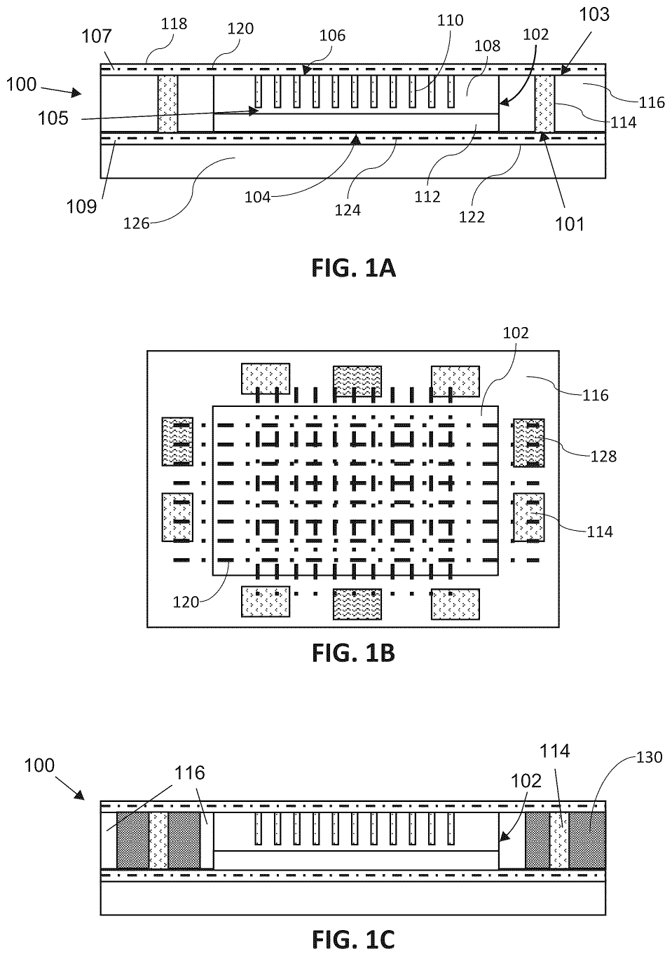

FIG. 1A illustrates a side view of a reconstituted element 100 that includes backside power delivery according to some embodiments. In FIG. 1A, power (including supplied power and/or ground) can be routed from the front side 101 of the reconstituted element 100 (also referred to herein as a front surface 101 of the reconstituted element 100) to a back side 103 of the reconstituted element 100 (also referred to herein as a back surface 103 of the reconstituted element 100). The reconstituted element can include an integrated device die (e.g., a processor or logic die 102) having a front surface 104 (also referred to as a front side 104 herein) and a back surface 106 (also referred to as a back side 106 herein). Although only one die 102 is illustrated, it should be appreciated that the reconstituted element 100 can comprise multiple dies disposed adjacent one another and spaced apart by dielectric 116. Die 102 may be a central processing unit (CPU), a graphics processing unit (GPU), a computer chip, a microprocessor, a field programmable gate array (FPGA), an application-specific integrated circuit (ASIC), or a memory chip or memory stack (e.g., static random-access memory (SRAM), dynamic random-access memory (DRAM), NAND, etc.) or a combination thereof. The die 102 can include a back portion 108 (e.g., formed of a semiconductor material such as silicon) that includes power delivery structures 110. The power delivery structures 110 can comprise, for example, buried power rails, through-silicon vias (TSVs), nano-TSVs, power vias, or backside contacts to source and/or drains, and so forth. The die 102 can include a front portion 112 that can include active devices (e.g., transistors formed during front end process) and signaling structures (e.g., build up layers including dielectrics and metallizations formed during back end of the line process). The front portion 112 can comprise routing lines connected to an active region 105 that can include active circuitry (e.g., one or more transistors, active devices, and device cells and circuits, or electronic components to process, store or transmit signals) at or near the front surface 104 of the die 102. The transistors of the active region 105 can accordingly connect to routing circuitry and devices in the front portion 112 and to the power delivery structures 110 (e.g., buried power rails, nano-TSVs, backside contacts to source and/or drains, etc.). As shown the power delivery structures 110 can extend from the back surface 106 of the die 102 through the back portion 108 to the active region 105 including the transistors. In some embodiments, the power delivery structures 110 extend only partially through a semiconductor material (e.g., silicon, gallium arsenide, indium phosphide, gallium nitride, silicon carbide or any other suitable semiconductor material) of the back portion 108 and can terminate within the semiconductor material to connect to the transistors of the active region 105. In some embodiments, the power delivery structures 110 provide power to transistors or device cells from the front side of the transistors or devices (e.g., contact to drain and source from front side via buried power rails), from the side of the transistor cells or devices (e.g., electrical contact to the source and drain region using buried power rails, power vias, etc.) or by directly contacting the source/drain regions from the backside (e.g., BSC). In other embodiments, the power delivery structures 110 can extend completely through the semiconductor material of the back portion 108 to deliver power to the routing circuitry of the front portion 112, and the routing circuitry of the front portion 112 can deliver power to the transistors of the active region 105.

In some embodiments, power can be delivered to active region 105 and the front portion 112 from the back portion 108 via the power delivery structures 110 (e.g., power rails or nano TSVs). The reconstituted element can include an interconnect structure (e.g., a redistribution layer (RDL) or back routing layer 118) comprising backside power delivery lines 120 embedded in a backside insulating material 107. In some embodiments, the reconstituted element can include a front routing layer 122 comprising power delivery lines 124 embedded in a frontside insulating material 109. The back routing layer 118 and front routing layer 122 can comprise one or multiple dielectric and metallization layers in various embodiments. Power rails 114 disposed in a reconstitution dielectric 116 can be configured to carry power to the back layer 118. Advantageously, the power rails 114 can be relatively large, for example from about 0.5 μm to about 5 μm in width (e.g., diameter if circular in cross section), which can enable transmission of power from the front side to the backside of the die 102 with minimal voltage loss (e.g., less than about 10%). In some embodiments, the power rails may be about 0.1 μm to 1 μm wide or 1 μm to 10 μm wide. The power rails 114 can comprise any suitable conductor, such as copper, aluminum, nickel, cobalt, etc. In some embodiments, the die 102 can have a thickness less than 20 μm, less than 10 μm, less than 1 μm or less than 0.5 μm.

In some embodiments, the reconstitution dielectric 116 can comprise an inorganic dielectric material, such as a silicon-containing dielectric, e.g., silicon oxide, silicon nitride, silicon oxynitride, silicon carbonitride, etc. The reconstitution dielectric 116 can comprise one or multiple layers of insulating or dielectric material. For example, in one embodiment, the reconstitution dielectric 116 can comprise a single dielectric layer, e.g., a single silicon oxide layer. In other embodiments, the reconstitution dielectric 116 can comprise multiple layers of insulating or dielectric material. For example, the reconstitution dielectric 116 can comprise a first dielectric layer (e.g., silicon nitride) and a second dielectric layer (e.g., silicon oxide) disposed over the first dielectric layer. In some embodiments, the first dielectric layer can comprise a conformal layer that encapsulates the die 102 and the second dielectric layer can comprise a filler material disposed over the first layer and extending to outer edges of the reconstituted element 100. In some embodiments, two or more second dielectric materials are used as filler materials. In other embodiments, the reconstitution dielectric 116 can comprise an organic dielectric, such as a molding compound, epoxy molding compound (EMC), resin, etc.

In some embodiments, the reconstituted element can be mounted to or affixed to another element 126. The element 126 can be, for example, a printed circuit board to which the reconstituted element is affixed, e.g., via a flip chip, ball grid array (BGA), etc., as explained in more detail below. In some embodiments, the reconstituted element can be bonded (e.g., direct bonded or direct hybrid bonded) to the element 126. For example, the element 126 can comprise a dummy element configured to provide cooling, structural support, and so forth. In some embodiments, the element 126 can comprise a device die, wafer, or substrate that includes features such as, for example, active circuitry (e.g., transistors), input/output, memory, cache, and so forth. In some embodiments, the element 126 can comprise an interposer die or a wafer that may be an active interposer or a passive interposer without any active devices. In other embodiments, the element 126 can comprise another reconstituted element in which one or more dies is embedded in a reconstitution dielectric (similar to reconstituted element 100). Additional elements (e.g., active elements, power supply elements, cooling elements, dummy elements, etc.) can be mounted to the back routing layer 118, e.g., by way of direct bonding, solder balls, etc.

FIG. 1B illustrates a bottom view of the reconstituted element 100 shown in FIG. 1A. As shown in FIG. 1B, the reconstituted element 100 can also include integrated voltage regulators (IVR) 128. The IVRs 128 can comprise electrical devices configured to control or regulate a voltage supplied to the die 102. The IVRs 128 can be mounted to (e.g., direct bonded to or soldered to or wire bonded to) the element 126. In some embodiments, power can be supplied through the element 126 and can be routed from the front side 101 of the reconstituted element 100 to the back side 103 of the reconstituted element 100 by way of the power rails 114 (e.g., through dielectric vias) extending through the reconstitution dielectric 116. The back routing layer 118 can transfer electrical power from the power rails 114 to the power delivery structures 110, which can transfer the power through the back portion 108 of the die 102. As explained above, in some embodiments, the vias of the power delivery structures 110 can extend partially through the back portion 108 to deliver power to the transistors of the active region 105 without routing the power along the routing circuitry of the front portion 112. In other embodiments, the vias of the power delivery structure 110 can extend through the die to the routing circuitry of the front portion 112, which can route the power to the transistors of the active region 105. In some embodiments, the power delivery lines 124 within front routing layer 122 can also provide some power to the die 102 from front side 101.

Beneficially, routing power to the active region 105 from the back surface 106 of the die 102 can allow for an increased number of signal lines at the front surface 104 of the die 102, since space at the front surface 104 that would otherwise be occupied by power lines can instead be used for signal lines and signals. In some embodiments, only signal pads are provided at the front surface 104 of the die 102 such that only signals are transferred to the active region 105 from the front surface 104. In some embodiments, at least 90% of the pads (e.g., at least 95% of the pads) at the front surface 104 are configured to transfer signals to the die 102 (as opposed to power). In some embodiments, at least 30% of the pads (e.g., at least 50% of the pads) at the front surface 104 are configured to transfer signals to the die 102 (as opposed to power or dummy pads). In some embodiments, at least 70% of the active or non-dummy pads at the front surface 104 are configured to transfer signals to the die 102. In some embodiments, greater than 50% of the active or non-dummy pads at the front surface 104 are configured to transfer signals to the die 102.

To form the reconstituted element 100, the die 102 can be mounted (e.g., adhered or direct bonded) to a temporary carrier or handle. The die 102 can be embedded in the reconstitution dielectric 116, and the power rails 114 can be provided in the dielectric 116. The dielectric 116, power rails 114, and die 102 can be thinned from the back to create a substantially flush back side of the reconstituted element. The power delivery structures 110 may be revealed after backside thinning or formed (e.g., drilled and filled) after backside thinning to make the contacts with the transistors and devices on the front side. The back routing layer 118 can be deposited and patterned to extend over the back surface 106 of the die 102, the back of the reconstitution dielectric 116 and back ends of the power rails 114. The front routing layer 122 can be provided over the front surface 104 of the die, the front of the reconstitution dielectric 116 and front ends of the power rails 114. One or both of the front and back routing layers 122, 118 can comprise redistribution layers (RDLs) to transfer signals laterally (e.g., laterally inwardly or outwardly) along the element 100. As explained above, one or both of the front and back routing layers 122, 118 can be prepared for direct bonding (e.g., hybrid bonding). As used herein, the delivery of power to the die 102 can comprise delivering electrical current to power devices on die 102 and can also comprise connecting the devices to electrical ground.

FIG. 1C illustrates a reconstituted element that is similar to the reconstituted element shown in FIG. 1A. However, in FIG. 1C, instead of being disposed in the reconstitution dielectric 116, the power rails 114 are instead surrounded on one or more sides by element 130 (e.g., semiconductor element or dummy silicon, glass, ceramic, etc.) or another material that is different from the reconstitution dielectric 116. In FIG. 1C, the power rails 114 can comprise through substrate vias (TSVs) provided through the element 130 or dummy semiconductor element 130. In some embodiments, the die 102 and elements 130 can be embedded in the reconstitution dielectric 116. In some embodiments, element 130 may comprise passive elements (e.g., capacitor, inductor, etc.) or other active elements. Beneficially, the use of elements 130 can serve to reduce stresses and provide structural support to the reconstituted element 100 as well as a thermal dissipation pathway.

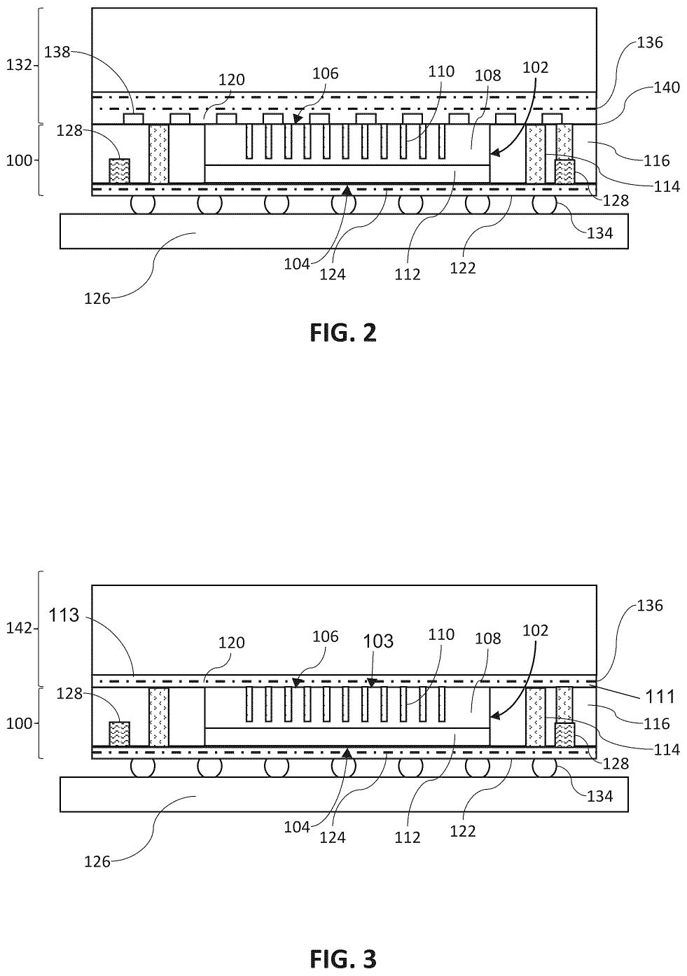

FIG. 2 illustrates an example embodiment of a device comprising a power delivery die 132 according to some embodiments. Unless otherwise noted, the structure depicted in FIG. 2 is generally similar to that depicted in FIGS. 1A-1C. The device in FIG. 2 includes integrated voltage regulators 128 disposed in the reconstitution dielectric 116. As shown, some IVRs 128 can connect to the redistribution layer 136 by way of vias or rails 114 that extend from the IVRs to the back side of the reconstituted element 100. Although IVRs 128 shown in FIG. 2 are connected to the front side routing 122, IVR 128 may also be connected from the top side of the IVR to back side routing 118 shown in FIG. 1 or a redistribution layer (RDL) 136. In FIG. 2, the element 126 may be a printed circuit board, and the reconstituted element is affixed and electrically connected to the element 126 via BGA balls 134. In other embodiments, the element 126 can comprise any other type of element, such as an integrated device die, another reconstituted element, an interposer (e.g., organic, inorganic or semiconductor, glass, etc.), a wafer, a substrate, a panel, etc. As above, the element 126 can alternatively be directly bonded (e.g., hybrid bonded) to the element 126. A power delivery die 132 can be bonded (e.g., direct bonded) to the reconstituted element 100. The power delivery die 132 can include a redistribution layer (RDL) 136. The power delivery die 132 can include pads 138 that can be electrically connected to corresponding pads (not shown) the reconstituted element 100. In some embodiments, as depicted in FIG. 2, the power delivery die 132 can be direct bonded (e.g. hybrid bonded) to the reconstituted element 100 at direct bonding interface 140. In the illustrated embodiment, therefore, the back routing layer may not be deposited on the back side 103 of the reconstituted element 100. Rather, the RDL 136 can be deposited on the power delivery die 132 and directly bonded to the reconstituted element 100 (e.g., directly bonded to the reconstitution dielectric 116, to the back surface 106 of the die 102 (which may include a bonding layer thereon), and to the power rails 114). In FIG. 2, the RDL 136 can comprise an interconnect element hybrid bonded to the reconstituted element 100. In some embodiments, the power delivery die 132 can be direct bonded (e.g., hybrid bonded) to a hybrid bonding layer formed on or over the reconstitution element 100.

While FIG. 2 shows that the power delivery die 132 includes a redistribution layer 136 and pads 138 and is direct bonded (e.g., direct hybrid bonded) to the reconstituted element 100, other configurations are possible. For example, in some embodiments, the redistribution layer 136 can be deposited onto the back surface 106 of the die 102 using semiconductor processing techniques such as lithography, etching, deposition, and polishing. In some embodiments, instead of a power delivery die 132 that is bonded to the reconstituted element 100, power delivery functionality can be directly deposited onto the back surface of the reconstituted element 100 and can form part of the reconstituted element 100. Beneficially, directly bonding the power die 132 to the reconstituted element 100 can enable for a more efficient process that utilizes higher numbers of pins for power (including ground). As explained above, as used herein, the delivery of power to the die 102 can comprise delivering electrical current to power devices on die 102 and can also comprise connecting the devices to electrical ground.

FIG. 3 illustrates an example assembly that includes at least one of a dummy die 142, a structural support die, a carrier die, a passive die, or a heat dissipating element. The dummy die 142 can be bonded (e.g., directly bonded) to the reconstituted element 100. In some embodiments, a dummy die 142 can be bonded (e.g., direct bonded) to a reconstituted element 100. The dummy die 142 can comprise an electrically inactive element in some embodiments, e.g., the dummy die 142 may be devoid of active circuitry (e.g., devoid of transistors). In some embodiments, the dummy die 142 can comprise passive circuits (e.g., capacitors, resistors, inductors, transformers, etc.); in other embodiments, the dummy die 142 can be devoid of passive devices. In some embodiments, the dummy die 142 can comprise a structural support element (e.g., a semiconductor material such as silicon) that provides mechanical support and/or reduces stresses imparted to the die 102. In some embodiments, the dummy die 142 can be used, for example, to assist in heat spreading to transfer heat away from the die 102. For example, in some embodiments, the dummy die 142 can comprise a heat spreader or heat sink. In some embodiments, the dummy die 142 can be used to provide cavity cooling. For example, the dummy die 142 can comprise one or more cooling cavities therein, and a cooling fluid can be provided through the cooling cavities to transfer heat from the die 102. In the embodiment of FIG. 3, the bonding interface 136 can be provided between opposing respective bonding layers of the dummy die 142 and the reconstituted element 100. For example, in FIG. 3, routing layer 111 can be provided on the back side 103 of the reconstituted element 100, and a routing layer 113 can be provided on the front of the dummy die 142. Respective bonding surfaces of the routing layers 111, 113 can be directly bonded along bonding interface 136. In other embodiments, however, the bonding interface 136 can be provided between routing layers of the dummy die 142 and the back side 103 of the reconstituted element 100 (e.g., the back side of the dielectric 116, the die 102, and the rails 114). In some embodiments, routing layer 111 can be provided on the back side 103 of the reconstituted element 100 and dummy die 142 can be directly bonded to the routing layer 111 without any separate routing layer 113 on the front of the dummy die 142.

In some embodiments, multiple elements can be bonded (e.g., direct bonded or direct hybrid bonded) together to form an assembly. For example, a second element comprising power delivery circuitry can be bonded (e.g., direct hybrid bonded) to the reconstituted element 100, and a third element, such as a dummy die, heat spreader, passive element, or liquid cooling element can be affixed to the second element, for example by direct bonding. In some embodiments, the second element and/or the third element can be reconstituted elements.

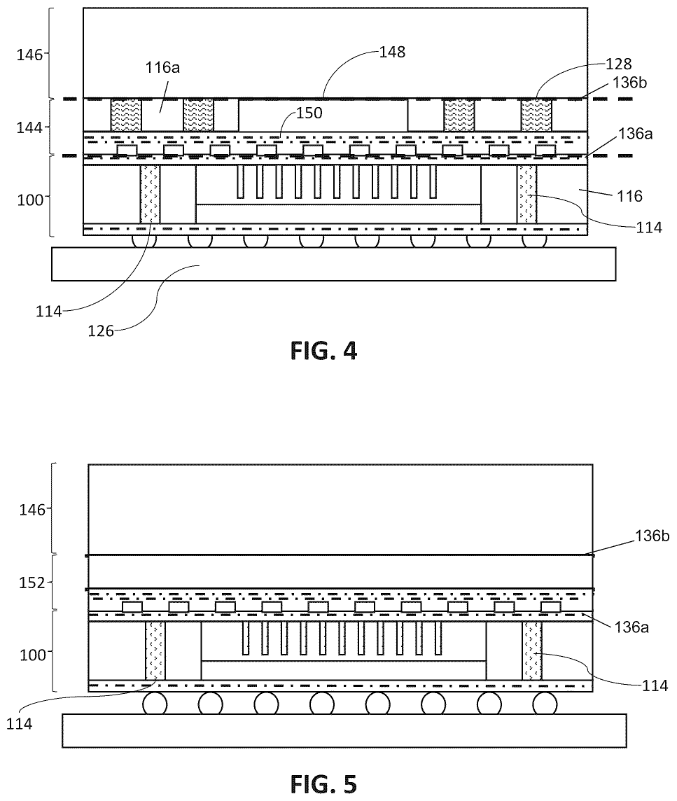

FIG. 4 illustrates an example embodiment in which a second reconstituted element 144 is bonded (e.g., direct hybrid bonded) to the reconstituted element 100 along bonding interface 136a, and a third element 146 (which may be similar to element 142 of FIG. 3, e.g., a dummy die, heat spreader, liquid cooling, etc.) is bonded (e.g., direct bonded) to the second reconstituted element 144 along bonding interface 136b, forming a stack. The second reconstituted element 144 can include integrated voltage regulators (IVRs) 128, spacers 148, and any other suitable active, passive or dummy devices. In some embodiments, the second reconstituted element 144 can include passives, integrated power delivery, and so forth. As shown in FIG. 4, in some embodiments, the second reconstituted element 144 can include a redistribution layer (RDL) 150, although in other embodiments the redistribution layer 150 may not be included in the second reconstituted element 144 and may instead be formed (e.g., deposited) onto the reconstituted element 100. In some embodiments, the spacer(s) 148 and IVRs 128 can be reconstituted in dielectric 116a, and the redistribution layer 150 can be deposited on the dielectric 116a, the spacer(s) 148, and the IVRs 128. A bonding surface of the RDL 150 can be hybrid bonded to the reconstituted element 100. Although not shown, through dielectric vias (e.g., conductive vias similar to power rails 114) can be provided through dielectric 116a.

FIG. 5 illustrates an example embodiment that is generally similar to that shown in FIG. 4. However, instead of a second reconstituted element 144, the second element 152 may not be reconstituted. For example, the second element 152 can be a wafer or a singulated part thereof. The second element 152 can include the same or similar functionality as the second reconstituted element 144. In some embodiments, for example, the second element 152 can comprise IVRs and/or passive devices patterned or formed therein. The second element 152 can be directly bonded to the reconstituted element 100 along bonding interface 136a, and the third element 146 can be directly bonded to the second element 152 along bonding interface 136b. It should be appreciated that, depending on the location of the respective bonding layers, the bonding interfaces 136a, 136b can be at other locations, e.g., along the back side 103 of the reconstituted element 100, etc.

FIGS. 4 and 5 depict assemblies in which the second element is either formed from a single piece (e.g., formed from a silicon wafer) or is a reconstituted element. However, other implementations are possible. For example, integrated voltage regulators, passives, integrated power delivery, spacers, and so forth can be bonded (e.g., direct bonded or direct hybrid bonded) to the reconstituted element 100. In some embodiments, a fill material (e.g., dielectric) can be deposited after the individual components are bonded to the reconstituted element 100.

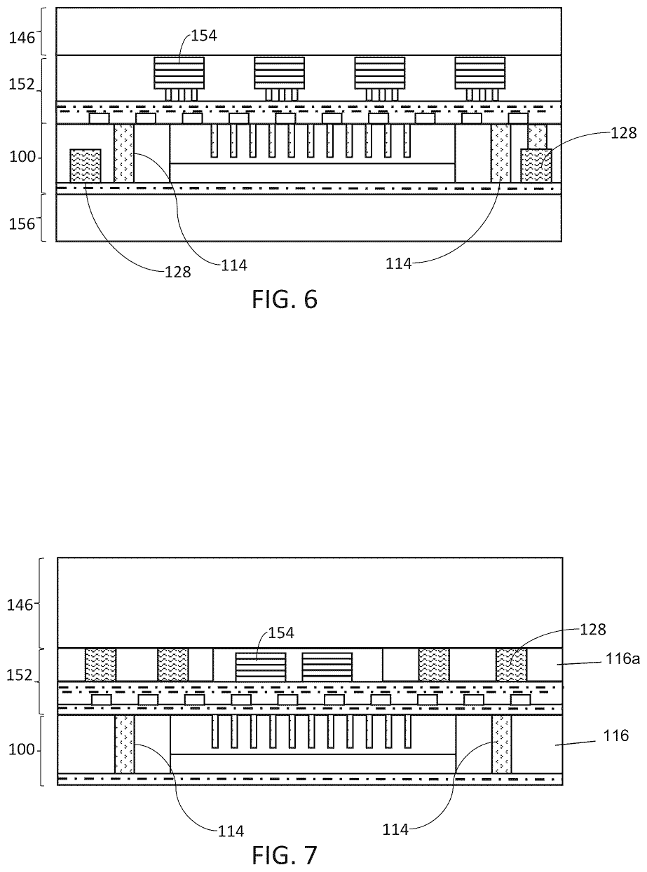

FIGS. 6 and 7 illustrate embodiments in which additional or alternative circuitry is included in a second element 152 that is bonded (e.g., direct bonded) to the reconstituted element 100. In FIG. 6, the second element 152 comprises a semiconductor element (e.g., a single semiconductor piece in some embodiments) which has memory banks 154 formed therein. In some embodiments, second element 152 can have memory devices (e.g., NAND, DRAM, SRAM, etc.). As illustrated in FIG. 6, in some embodiments, a fourth element 156 can be bonded (e.g., direct bonded) to the front surface 104 of the reconstituted element 100. The fourth element 156 can include, for example, electrical signal input/output, optical signal input/output, cache, and so forth. As explained above, the element 146 can comprise a dummy element that can provide at least one of structural support and heat transfer to the assembly.

FIG. 7 is similar to FIG. 6, except that instead of a single element with memory banks formed therein, the second element 152 is a reconstituted element having integrated voltage regulators, spacers, memory banks (or memory devices), and/or other devices embedded in dielectric 116a. The use of direct bonding techniques in FIGS. 6-7 can enable high speed connection between memory banks 154 and logic die 102 and with high pin count due to the fine pitches enabled by direct bonding processes.

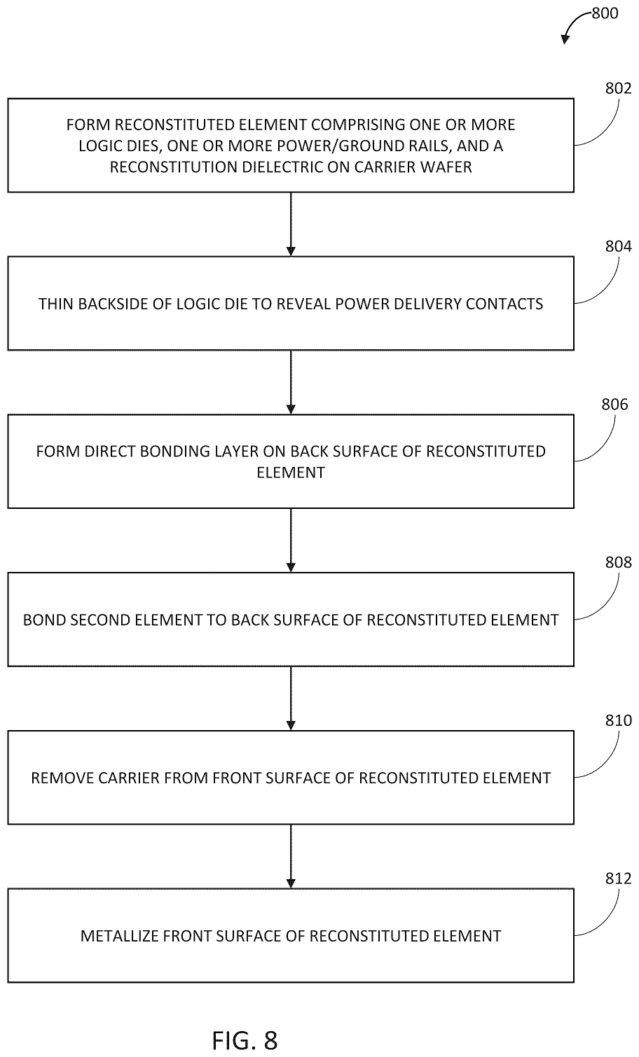

FIG. 8 is a flowchart that illustrates an example process 800 for making an assembly including backside power delivery according to some embodiments. At block 802, a reconstituted wafer can be formed. For example, in a die-to-wafer bonding process, known good logic dies can be bonded (e.g., directly bonded) to a carrier wafer. The front side of the logic dies (e.g., the side nearest the logic circuitry) can be bonded to the carrier wafer. Integrated voltage regulators, passives, and so forth can also be directly bonded to the carrier wafer, although in some embodiments they may be formed or mounted by other means, such as deposition or soldering, or such elements may not be present. The gaps between the dies can be filled with a dielectric material (for example, through a deposition process, e.g., one or more layers of silicon nitride, silicon oxide, etc.). One or more power and/or ground rails can be formed within the dielectric and can extend from a front surface of the dielectric to a back surface of the dielectric. The power and/or ground rails can be formed after the dielectric, for example by selectively etching some areas of the dielectric material to provide gaps that can be filled by depositing, electroplating, and so forth. Alternatively, the power and/or ground rails can be formed before the dielectric, for example electroplating the power rails (e.g., copper pillars) followed by dielectric deposition. Each logic die and its associated dielectric material, power/ground rails, and other associated circuitry can comprise a reconstituted element. A reconstituted wafer can include one reconstituted element or more than one reconstituted element. In some embodiments, a reconstituted element can include one or more dies, the one or more dies comprising one or more logic and/or memory dies.

At block 804, the backside of reconstituted element can be thinned, for example by chemical mechanical polishing (CMP), etching, or backgrinding, to reveal power delivery contacts. The power delivery contacts can be, for example, contact pads that are in electrical contact with or part of buried power rails, nano-TSVs, power vias or backside contacts (BSCs) to source and/or drains (e.g., backside direct source contacting) and so forth. After thinning, at block 806 a hybrid bonding interface layer can optionally be formed on the exposed back surface of the reconstituted element to facilitate the subsequent bonding of additional dies, dummy silicon, and so forth.

At block 808, a second element can be bonded to the back surface of the reconstituted element. As discussed above, the second element can be, for example, a power delivery die, dummy silicon, reconstituted die and so forth.

At block 810, the carrier can be removed from the reconstituted element, thereby exposing a front surface of the reconstituted element. The front surface can then be further processed, for example by polishing. At block 812, the front surface of the reconstituted element can be metallized.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 908a and/or 908b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements. As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

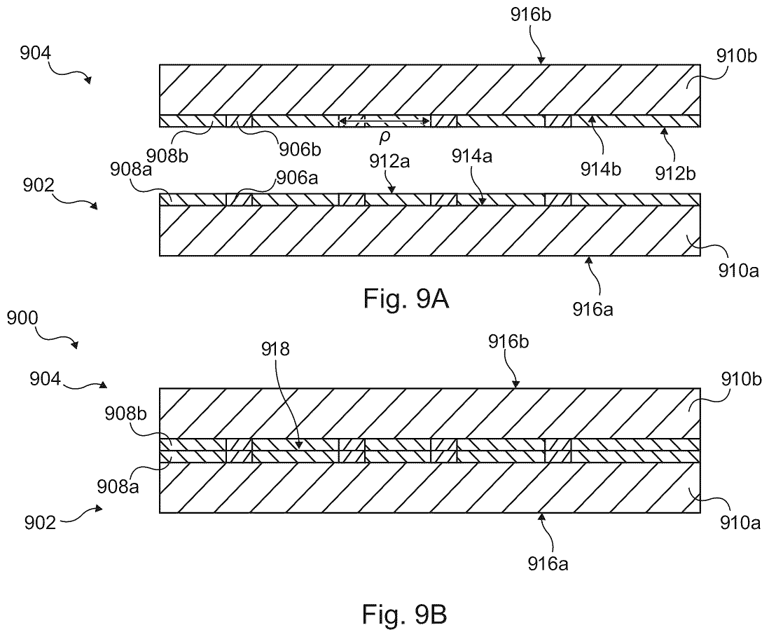

FIGS. 9A and 9B schematically illustrate cross-sectional side views of first and second elements 902, 904 prior to and after, respectively, a process for forming a directly bonded structure, and more particularly a hybrid bonded structure, according to some embodiments. In FIG. 9B, a bonded structure 900 comprises the first and second elements 902 and 904 that are directly bonded to one another at a bond interface 918 without an intervening adhesive. Conductive features 906a of a first element 902 may be electrically connected to corresponding conductive features 906b of a second element 904. In the illustrated hybrid bonded structure 900, the conductive features 906a are directly bonded to the corresponding conductive features 906b without intervening solder or conductive adhesive.

The conductive features 906a and 906b of the illustrated embodiment are embedded in, and can be considered part of, a first bonding layer 908a of the first element 902 and a second bonding layer 908b of the second element 904, respectively. Field regions of the bonding layers 908a, 908b extend between and partially or fully surround the conductive features 906a, 906b. The bonding layers 908a, 908b can comprise layers of non-conductive materials suitable for direct bonding, as described above, and the field regions are directly bonded to one another without an adhesive. The non-conductive bonding layers 908a, 908b can be disposed on respective front sides 914a, 914b of base substrate portions 910a, 910b.

The first and second elements 902, 904 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 902, 904, and back-end-of-line (BEOL) interconnect layers over such semiconductor portions. The bonding layers 908a, 908b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 910a, 910b, and can electrically communicate with at least some of the conductive features 906a, 906b. Active devices and/or circuitry can be disposed at or near the front sides 914a, 914b of the base substrate portions 910a, 910b, and/or at or near opposite backsides 916a, 916b of the base substrate portions 910a, 910b. In other embodiments, the base substrate portions 910a, 910b may not include active circuitry, but may instead comprise dummy substrates, passive interposers, passive optical elements (e.g., glass substrates, gratings, lenses), etc. The bonding layers 908a, 908b are shown as being provided on the front sides of the elements, but similar bonding layers can be additionally or alternatively provided on the back sides of the elements.

In some embodiments, the base substrate portions 910a, 910b can have significantly different coefficients of thermal expansion (CTEs), and bonding elements that include such different based substrate portions can form a heterogenous bonded structure. The CTE difference between the base substrate portions 910a and 910b, and particularly between bulk semiconductor (typically single crystal) portions of the base substrate portions 910a, 910b, can be greater than 5 ppm/° C. or greater than 10 ppm/° C. For example, the CTE difference between the base substrate portions 910a and 910b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 910a, 910b can comprise optoelectronic single crystal materials, including perovskite materials, that are useful for optical piezoelectric or pyroelectric applications, and the other of the base substrate portions 910a, 910b comprises a more conventional substrate material. For example, one of the base substrate portions 910a, 910b comprises lithium tantalate (LiTaO3) or lithium niobate (LiNbO3), and the other one of the base substrate portions 910a, 910b comprises silicon (Si), quartz, fused silica glass, sapphire, or a glass. In other embodiments, one of the base substrate portions 910a, 910b comprises a III-V single semiconductor material, such as gallium arsenide (GaAs) or gallium nitride (GaN), and the other one of the base substrate portions 910a, 910b can comprise a non-III-V semiconductor material, such as silicon (Si), or can comprise other materials with similar CTE, such as quartz, fused silica glass, sapphire, or a glass. In still other embodiments, one of the base substrate portions 910a, 910b comprises a semiconductor material and the other of the base substrate portions 910a, 910b comprises a packaging material, such as a glass, organic or ceramic substrate.

In some arrangements, the first element 902 can comprise a singulated element, such as a singulated integrated device die. In other arrangements, the first element 902 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 904 can comprise a singulated element, such as a singulated integrated device die. In other arrangements, the second element 904 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 902, 904 are shown, any suitable number of elements can be stacked in the bonded structure 900. For example, a third element (not shown) can be stacked on the second element 904, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 902. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 908a, 908b, the bonding layers 908a, 908b can be prepared for direct bonding. Non-conductive bonding surfaces 912a, 912b at the upper or exterior surfaces of the bonding layers 908a, 908b can be prepared for direct bonding by polishing, for example, by chemical mechanical polishing (CMP). The roughness of the polished bonding surfaces 912a, 912b can be less than 30 Å rms. For example, the roughness of the bonding surfaces 912a and 912b can be in a range of about 0.1 Å rms to 15 Å rms, 0.5 Å rms to 10 Å rms, or 1 Å rms to 5 Å rms. Polishing can also be tuned to leave the conductive features 906a, 906b recessed relative to the field regions of the bonding layers 908a, 908b.

Preparation for direct bonding can also include cleaning and exposing one or both of the bonding surfaces 912a, 912b to a plasma and/or etchants to activate at least one of the surfaces 912a, 912b. In some embodiments, one or both of the surfaces 912a, 912b can be terminated with a species after activation or during activation (e.g., during the plasma and/or etch processes). Without being limited by theory, in some embodiments, the activation process can be performed to break chemical bonds at the bonding surface(s) 912a, 912b, and the termination process can provide additional chemical species at the bonding surface(s) 912a, 912b that alters the chemical bond and/or improves the bonding energy during direct bonding. In some embodiments, the activation and termination are provided in the same step, e.g., a plasma to activate and terminate the surface(s) 912a, 912b. In other embodiments, one or both of the bonding surfaces 912a, 912b can be terminated in a separate treatment to provide the additional species for direct bonding. In various embodiments, the terminating species can comprise nitrogen. For example, in some embodiments, the bonding surface(s) 912a, 912b can be exposed to a nitrogen-containing plasma. Other terminating species can be suitable for improving bonding energy, depending upon the materials of the bonding surfaces 912a, 912b. Further, in some embodiments, the bonding surface(s) 912a, 912b can be exposed to fluorine. For example, there may be one or multiple fluorine concentration peaks at or near a bond interface 918 between the first and second elements 902, 904. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 900, the bond interface 918 between two non-conductive materials (e.g., the bonding layers 908a, 908b) can comprise a very smooth interface with higher nitrogen (or other terminating species) content and/or fluorine concentration peaks at the bond interface 918. In some embodiments, the nitrogen and/or fluorine concentration peaks may be detected using various types of inspection techniques, such as SIMS techniques. The polished bonding surfaces 912a and 912b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 908a and 908b can be directly bonded to one another without an adhesive. In some embodiments, the elements 902, 904 are brought together at room temperature, without the need for application of a voltage, and without the need for application of external pressure or force beyond that used to initiate contact between the two elements 902, 904. Contact alone can cause direct bonding between the non-conductive surfaces of the bonding layers 908a, 908b (e.g., covalent dielectric bonding). Subsequent annealing of the bonded structure 900 can cause the conductive features 906a, 906b to directly bond.

In some embodiments, prior to direct bonding, the conductive features 906a, 906b are recessed relative to the surrounding field regions, such that a total gap between opposing contacts after dielectric bonding and prior to anneal is less than 15 nm, or less than 10 nm. Because the recess depths for the conductive features 906a and 906b can vary across each element, due to process variation, the noted gap can represent a maximum or an average gap between corresponding conductive features 906a, 906b of two joined elements (prior to anneal). Upon annealing, the conductive features 906a and 906b can expand and contact one another to form a metal-to-metal direct bond.

During annealing, the conductive features 906a, 906b (e.g., metallic material) can expand while the direct bonds between surrounding non-conductive materials of the bonding layers 908a, 908b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 906a, 906b can comprise discrete pads, contacts, electrodes, or traces at least partially embedded in the non-conductive field regions of the bonding layers 908a, 908b. In some embodiments, the conductive features 906a, 906b can comprise exposed contact surfaces of TSVs (e.g., through silicon vias).

As noted above, in some embodiments, in the elements 902, 904 of FIG. 1A prior to direct bonding, portions of the respective conductive features 906a and 906b can be recessed below the non-conductive bonding surfaces 912a and 912b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 906a, 906b or to average depths of the recesses relative to local non-conductive field regions. Even for an individual conductive feature 906a, 906b, the vertical recess can vary across the feature, and so can be measured at or near the lateral middle or center of the cavity in which a given conductive feature 906a, 906b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 906a, 906b across the direct bond interface 918 (e.g., small or fine pitches for regular arrays).

In some embodiments, a pitch p of the conductive features 906a, 906b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 906a and 906b to one of the lateral dimensions (e.g., a diameter) of the bonding pad is less than is less than 20, or less than 10, or less than 5, or less than 3 and sometimes desirably less than 2. In various embodiments, the conductive features 906a and 906b and/or traces can comprise copper or copper alloys, although other metals may be suitable, such as nickel, aluminum, or alloys thereof. The conductive features disclosed herein, such as the conductive features 906a and 906b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 902, 904, as shown, the orientations of one or more conductive features 906a, 906b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 906b in the bonding layer 908b (and/or at least one internal conductive feature, such as a BEOL feature) of the upper element 904 may be tapered or narrowed upwardly, away from the bonding surface 912b. By way of contrast, at least one conductive feature 906a in the bonding layer 908a (and/or at least one internal conductive feature, such as a BEOL feature) of the lower element 902 may be tapered or narrowed downwardly, away from the bonding surface 912a. Similarly, any bonding layers (not shown) on the backsides 916a, 916b of the elements 902, 904 may taper or narrow away from the backsides, with an opposite taper orientation relative to front side conductive features 906a, 906b of the same element.

As described above, in an anneal phase of hybrid bonding, the conductive features 906a, 906b can expand and contact one another to form a metal-to-metal direct bond. In some embodiments, the materials of the conductive features 906a, 906b of opposite elements 902, 904 can interdiffuse during the annealing process. In some embodiments, metal grains grow into each other across the bond interface 918. In some embodiments, the metal is or includes copper, which can have grains oriented along the 111 crystal plane for improved copper diffusion across the bond interface 918. In some embodiments, the conductive features 906a and 906b may include nanotwinned copper grain structure, which can aid in merging the conductive features during anneal. There is substantially no gap between the non-conductive bonding layers 908a and 908b at or near the bonded conductive features 906a and 906b. In some embodiments, a barrier layer may be provided under and/or laterally surrounding the conductive features 906a and 906b (e.g., which may include copper). In other embodiments, however, there may be no barrier layer under the conductive features 906a and 906b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. An assembly comprising:
a reconstituted element having a front surface and a back surface, the reconstituted element comprising:
a semiconductor die having a front side and a back side, the semiconductor die including circuitry closer to the front side than to the back side and a via extending from the back side of the semiconductor die to connect to the circuitry;
an insulating material disposed along a side surface of the semiconductor die;
a power rail extending from the front surface to the back surface of the reconstituted element and configured to deliver power to the semiconductor die; and
an interconnect structure configured to electrically connect the power rail to the via and to deliver power to the semiconductor die from the back side of the semiconductor die.

2. The assembly of claim 1, wherein the insulating material comprises an inorganic dielectric.

3. The assembly of claim 2, wherein the insulating material comprises silicon oxide.

4. The assembly of claim 1, wherein the insulating material comprises an organic dielectric.

5. The assembly of claim 1, wherein the interconnect structure comprises a redistribution layer disposed on the back surface of the reconstituted element.

6. The assembly of claim 1, wherein the interconnect structure comprises an interconnect element that is hybrid bonded to the back side of the semiconductor die.

7. The assembly of claim 1, wherein the interconnect structure comprises one or more metallization layers.

8. The assembly of claim 1, further comprising a power delivery die,
wherein the power delivery die is hybrid bonded to the back surface of the reconstituted element.

9. The assembly of claim 8, wherein the power delivery die comprises a redistribution layer.

10. The assembly of claim 1, wherein the reconstituted element further comprises an integrated voltage regulator.

11. The assembly of claim 1, further comprising a dummy die, wherein the dummy die is directly bonded to the back surface of the reconstituted element.

12. The assembly of claim 1, further comprising a second reconstituted element, the second reconstituted element comprising:
an integrated voltage regulator; and
integrated power delivery circuitry,
wherein the second reconstituted element is hybrid bonded to the reconstituted element.

13. The assembly of claim 12, further comprising a dummy die, the dummy die directly bonded to the second reconstituted element.

14. The assembly of claim 12, further comprising a stack, wherein the stack comprises a dummy die directly bonded to the second reconstituted element.

15. The assembly of claim 1, further comprising:
an integrated voltage regulator element hybrid bonded to the reconstituted element.

16. The assembly of claim 1, wherein the reconstituted element further comprises a dummy semiconductor element, wherein the power rail is disposed in the dummy semiconductor element.

17. The assembly of claim 1, wherein the reconstituted element further comprises an integrated voltage regulator,
wherein the assembly further comprises a power delivery die, the power delivery die comprising a one or more memory banks.

18. The assembly of claim 17, further comprising an optical input/output system, the optical input/output system bonded to the front surface of the reconstituted element.

19. The assembly of claim 1, further comprising:
a second reconstituted element hybrid bonded to the reconstituted element,
wherein the second reconstituted element comprises:
integrated power delivery circuitry;
one or more memory banks; and
one or more integrated voltage regulators.

20. The assembly of claim 1, wherein the circuitry comprises one or more transistors.

21. The assembly of claim 1, wherein the semiconductor die has a thickness less than 5 μm.

22. The assembly of claim 1, wherein the semiconductor die has a thickness less than 1 μm.

23. The assembly of claim 1, wherein the semiconductor die is a logic die or a processor die.

24. An assembly comprising:
an insulating material;
a power rail extending through the insulating material;
an integrated device die at least partially embedded in the insulating material, the integrated device die having a front side and a back side, the integrated device die including circuitry closer to the front side than to the back side and a power delivery structure extending from the back side of the integrated device die to connect to the circuitry; and
an interconnect structure over the insulating material, the power rail, and the back side of the integrated device die, the interconnect structure configured to deliver power between the power rail and the power delivery structure at the back side of the integrated device die.

25. The assembly of claim 24, wherein the insulating material comprises an inorganic dielectric material.

26. The assembly of claim 24, further comprising a power delivery die hybrid bonded to the interconnect structure.

27. The assembly of claim 24, further comprising a dummy die, wherein the dummy die is directly bonded to the interconnect structure.

28. A method for forming a bonded structure having backside power delivery, the method comprising:
forming a bonding surface on a back surface of a reconstituted element, the reconstituted element having a front surface and a back surface,
wherein the reconstituted element comprises:
a semiconductor die having a front side and a back side, the semiconductor die including circuitry closer to the front side than to the back side and a via extending from the back side of the semiconductor die to connect to the circuitry;
an insulating material disposed along a side surface of the semiconductor die;
a power rail extending from the front surface to the back surface of the reconstituted element and configured to deliver power to the semiconductor die; and
an interconnect structure configured to electrically connect the power rail to the via and to deliver power to the semiconductor die from the back side of the semiconductor die; and
directly bonding a second element to the bonding surface of the reconstituted element.

29. The method of claim 28, wherein the second element comprises an integrated voltage regulator.
